(19) United States
(12) Patent Application Publication
(10) Pub. No.: US 2009/0187363 A1
(43) Pub. Date: Jul. 23, 2009

(54) Method for optimization of a frequency spectrum

(75) Inventors: Rong-Ching Wu, Dashu Township (TW); Ching-Tai Chiang, Dashu Township (TW); Yung-Chun Wu, Dashu Township (TW)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: I SHOU UNIVERSITY, Dashu Township (TW)

(21) Appl. No.: 12/319,930

(22) Filed: Jan. 13, 2009

(30) Foreign Application Priority Data
Jan. 18, 2008 (TW) 097102035

(51) Int. Cl. G01R 23/16; G06F 19/00

(52) U.S. Cl. 702/77; 702/76

(57) ABSTRACT

A method for optimization of a frequency spectrum includes the following steps: sampling a time domain signal to obtain an initial sampling signal based upon a first subset of sample points; transforming the initial sampling signal to a frequency domain signal; determining a frequency parameter and an amplitude parameter for each of harmonic components of the frequency domain signal; establishing a leakage energy equation and a graduation shifting quantity; determining an optimum number of sample points that will result in minimum leakage energy; obtaining an adjusted sampling signal based on a second subset of the sample points, wherein the number of the sample points in the second subset is equal to the optimum number; and transforming the adjusted sampling signal to an optimized frequency domain signal having harmonic components associated with graduations of an optimized frequency spectrum, wherein the graduations are calculated based upon the graduation shifting quantity.

### CROSS-REFERENCE TO RELATED APPLICATION

This application claims priority to Taiwanese Application No. 097102035, filed Jan. 18, 2008, the disclosure of which is incorporated herein by reference.

### BACKGROUND OF THE INVENTION

1. Field of the Invention

The present invention relates to a method for optimization of a frequency spectrum, more particularly to a method for optimization of a frequency spectrum by shifting graduations of the frequency spectrum to reduce an error caused by a leakage effect.

2. Description of the Related Art

General commercial harmonic measuring devices, such as a spectrum analyzer, a harmonic analyzer, a distortion analyzer, digital harmonic measuring equipments, etc., utilize Fast Fourier Transform (FFT) to transform a time domain sampling signal to a frequency domain signal for spectrum analysis, although each of the harmonic measuring devices has a different function. However, when a harmonic frequency of the sampling signal is not a multiple of frequency resolution, there are a picket-fence effect associated with frequency distortion and a leakage effect associated with amplitude distortion when transforming the time domain sampling signal to a frequency domain signal using FFT.

Some methods have been proposed heretofore to alleviate the above disadvantages. In a windowing method, a product of the sampling signal and a window function is used for maintaining continuity in a wave so as to eliminate side lobe components in the spectrum. In a zero complement method, duration of sampling is extended for a multiple of a period of a time domain signal that is sampled, and an extending part of the sampling signal is complemented by zero. Although the windowing method can reduce the leakage effect, a bandwidth of a main lobe is increased, and amplitude of the main lobe is decreased. Although leakage energy is eliminated in the frequency spectrum, components in the frequency spectrum cannot accurately represent the time domain signal. While the zero complement method can reduce the picket-fence effect, the amplitude in the spectrum is decreased, such that this method cannot reduce the leakage effect. Accordingly, characteristics of the time domain signal are changed in the windowing method and the zero complement method. Thus, characteristics of the frequency spectrum are different from those of the time domain signal, such that the frequency spectrum cannot represent actual parameters of the sampling signal. Therefore, a method for shifting graduations of a frequency spectrum to conform to the characteristics of the time domain signal has been proposed heretofore. This method utilizes a common factor of harmonic frequencies as a graduation interval so as to maintain the characteristics of the time domain signal.

However, this conventional method has unavoidable disadvantages. First, there is a great difference between the common factor and an original graduation interval such that the method cannot be used in an actual practice. Second, the graduations are shifted to conform to the harmonic frequencies in this method. However, there is an error in the harmonic frequencies obtained by calculation, such that the common factor based upon the harmonic frequencies is not an optimum graduation interval.

### SUMMARY OF THE INVENTION

Therefore, an object of the present invention is to provide a method for optimization of a frequency spectrum that maintains characteristics of a sampling signal, and that can reduce a leakage effect and a picket-fence effect so as to enhance accuracy of the frequency spectrum.

Accordingly, a method for optimization of a frequency spectrum of the present invention comprises the following steps:

a) sampling a time domain signal at a number of sample points, and obtaining an initial sampling signal based on a first subset of the sample points;

b) transforming the initial sampling signal to a frequency domain signal having harmonic components associated with graduations of an initial frequency spectrum;

c) determining a frequency parameter and an amplitude parameter for each of the harmonic components of the frequency domain signal obtained in step b);

d) establishing a leakage energy equation and determining a graduation shifting quantity based upon the frequency parameters and the amplitude parameters obtained in step c), the number of sample points in the first subset, and the graduations of the initial frequency spectrum that are associated with the harmonic components of the frequency domain signal in step b);

e) determining an optimum number of sample points that will result in a minimum value of the leakage energy equation;

f) obtaining an adjusted sampling signal based on a second subset of the sample points, wherein the number of the sample points in the second subset is equal to the optimum number obtained in step e); and

g) transforming the adjusted sampling signal to an optimized frequency domain signal having harmonic components associated with graduations of an optimized frequency spectrum, wherein the graduations of the optimized frequency spectrum are calculated based upon the graduations of the initial frequency spectrum, the graduation shifting quantity determined in step d), the number of sample points in the first subset, and the optimum number obtained in step e).

Therefore, the harmonic components of the optimized frequency spectrum correspond to the graduations calculated in step g), such that the leakage effect and the picket-fence effect are reduced, and the frequency spectrum is relatively accurate via the method according to this invention.

### BRIEF DESCRIPTION OF THE DRAWINGS

Other features and advantages of the present invention will become apparent in the following detailed description of the preferred embodiment with reference to the accompanying drawings, of which:

FIG. 1 is a flow chart illustrating a preferred embodiment of a method for optimization of a frequency spectrum according to the present invention;

FIG. 2 is a flow chart illustrating steps for determining an amplitude parameter and a frequency parameter in the method for optimization of a frequency spectrum according to the present invention;

FIG. 3 is a schematic plot illustrating a frequency spectrum of a sampling signal;

FIG. 4 is a schematic plot showing an initial frequency spectrum of the preferred embodiment according to the present invention;

FIG. 5 is a schematic plot showing a relationship between a number of sample points and frequency differences of harmonic components in FIG. 4 of the preferred embodiment according to the present invention;

FIG. 6 is a schematic plot showing a relationship between the number of sample points and leakage energy of the preferred embodiment according to the present invention;

FIG. 7 is a plot showing the sampling signal compared with an adjusted sampling signal of the preferred embodiment according to the present invention;

FIG. 8 is a schematic plot showing an optimized frequency spectrum of the preferred embodiment according to the present invention;

FIG. 9 shows tables to illustrate parameters obtained by Fast Fourier Transform and the method of the preferred embodiment according to the present invention; and

FIG. 10 is a schematic plot showing an optimized frequency spectrum of a non-periodic signal obtained by the method of the preferred embodiment according to the present invention.

### DETAILED DESCRIPTION OF THE PREFERRED EMBODIMENT

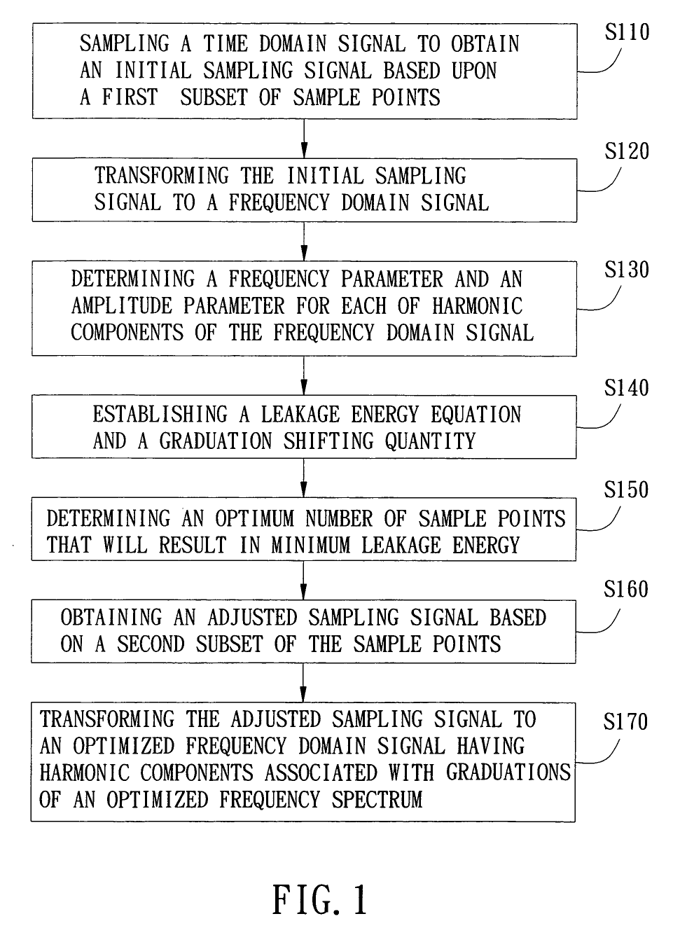

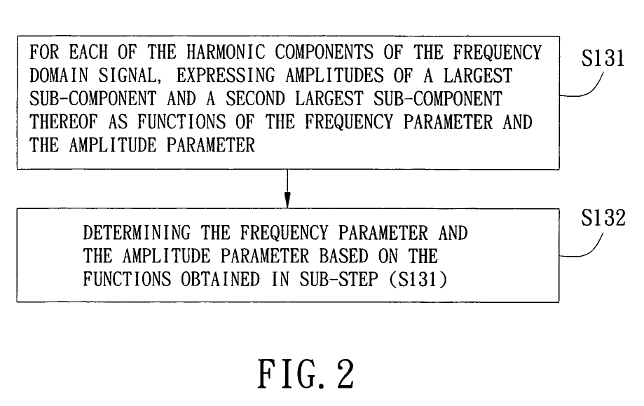

Referring to FIGS. 1 and 2, the preferred embodiment of a method for optimization of a frequency spectrum according to the present invention includes the following steps.

The first step (S110) is to sample a time domain signal at a number of sample points, followed by obtaining an initial sampling signal based on a first subset of the sample points. The time domain signal is sampled according to a predetermined sampling frequency and during a predetermined duration of sampling. The sampling frequency is more than twice the highest frequency of the time domain signal to conform with sampling principles. At least three identical waveforms are contained in the time domain signal during the duration of sampling when the time domain signal is a periodic signal, such that the initial sampling signal is able to present characteristics of the time domain signal.

The periodic time domain signal can be considered as a combination of a plurality of linear independent vectors, and a set of the linear independent vectors is a sinusoidal function. The time domain signal x(t) can be expressed by a Fourier series, that is,

$$x ( t ) = \frac{a ( 0 )}{2} + {\sum }_{m = 1}^{∞} ( a ( m ) cos \frac{2 π m}{T} t + b ( m ) sin \frac{2 π m}{T} t ) , 0 \leq t \leq T , \\ wherein \\ a ( m ) = \frac{2}{T} {\int }_{0}^{0 + T} x ( t ) cos \frac{- 2 π mt}{T} d t , \\ b ( m ) = \frac{2}{T} {\int }_{0}^{0 + T} x ( t ) cos \frac{- 2 π mt}{T} d t . \qquad ( 1 )$$

Equation 1 can be expressed in a complex form:

$$x ( t ) = {\sum }_{m = - ∞}^{∞} c ( m ) exp ( \frac{j 2 π m}{T} t ) , \\ 0 \leq t \leq T , \\ wherein \\ c ( m ) = \frac{1}{T} {\int }_{0}^{0 + T} x ( t ) exp ( \frac{- j 2 π m}{T} t ) d t . \qquad ( 2 )$$

In this embodiment, the duration of sampling is T seconds to obtain the number of sample points, followed by obtaining the initial sampling signal according to a number N of the sample points in the first subset.

In step (S120), Fast Fourier Transform (FFT) or Discrete Fourier Transform (DFT) is used to transform the initial sampling signal to a frequency domain signal having harmonic components associated with graduation of an initial frequency spectrum. In this embodiment, DFT is used to transform the initial sampling signal, followed by obtaining the initial frequency spectrum. The initial sampling signal can be represented by

$$x ( n ) = \frac{1}{N} + {\sum }_{m = 0}^{N - 1} X ( m ) exp ( \frac{j 2 π mn}{N} ) , \\ and \\ X ( m ) = {\sum }_{m = 0}^{N - 1} x ( n ) exp ( \frac{j 2 π mn}{N} ) , \qquad ( 3 )$$

wherein n and m are ordinals of the graduations of the initial frequency spectrum and range from 0 to N−1, x(n) is a scalar quantity at the n^{th} graduation, and X(m) is a vector at the m^{th} graduation.

A periodic signal can be considered as a combination of a plurality of independent harmonic components. It is assumed that the initial sampling signal is a combination of K independent harmonic components, and therefore the initial sampling signal x(n) can be represented by

$$x ( n ) = {\sum }_{k = 1}^{K} {A}_{x} ( k ) cos ( 2 π {f}_{x} ( k ) n / N + {φ}_{x} ( k ) ) , \qquad ( 4 )$$

wherein Aₓ(k) is an amplitude parameter of the k^{th} harmonic component, φₓ(k) is a phase parameter of the k^{th} harmonic component, and fₓ(k) is a frequency parameter of the k^{th} harmonic component.

According to Equations 3 and 4, the initial frequency spectrum can be represented by

$$X ( m ) = \frac{1}{2} {\sum }_{k = 1}^{K} {\sum }_{n = 0}^{N - 1} {A}_{x} ( k ) {e}^{- j 2 π mn / N} ( \begin{matrix}{e}^{j ( 2 π {f}_{x} ( k ) n / N + {φ}_{x} ( k ) )} + \\ {e}^{- j ( 2 π {f}_{x} ( k ) n / N + {φ}_{x} ( k ) )}\end{matrix} ) . \qquad ( 5 )$$

Each of the harmonic components can be separated into a real part and an imaginary part. After rearranging Equation 5, the initial frequency spectrum can be represented by

$$X ( m ) = {\sum }_{k = 1}^{K} \frac{{A}_{x} ( k )}{2} {e}^{j {φ}_{x} ( k )} {\sum }_{n = 0}^{N - 1} {e}^{\frac{j 2 π ( {f}_{x} ( k ) - m )}{N} n} + {\sum }_{k = 1}^{K} \frac{{A}_{x} ( k )}{2} {e}^{- j {φ}_{x} ( k )} {\sum }_{n = 0}^{N - 1} {e}^{\frac{- j 2 π ( {f}_{x} ( k ) - m )}{N} n} . \qquad ( 6 )$$

According to the following formula,

$${\sum }_{n = 0}^{N - 1} {e}^{pm} = \frac{1 - {e}^{Np}}{1 - {e}^{p}} \qquad ( 7 )$$

Equation 6 can be rearranged as

$$X ( m ) = {\sum }_{k = 1}^{K} \frac{{A}_{x} ( k )}{2} {e}^{j {φ}_{x} ( k )} \frac{1 - {e}^{j 2 π ( {f}_{x} ( k ) - m )}}{1 - {e}^{j 2 π ( {f}_{x} ( k ) - m ) / N}} + {\sum }_{k = 1}^{K} \frac{{A}_{x} ( k )}{2} {e}^{- j {φ}_{x} ( k )} \frac{1 - {e}^{- j 2 π ( {f}_{x} ( k ) - m )}}{1 - {e}^{- j 2 π ( {f}_{x} ( k ) - m ) / N}} . \qquad ( 8 )$$

Equation 8 can be expressed in a vector form, i.e.,

$$X ( m ) = {\sum }_{k = 1}^{K} [ A ( k , m ) ∠φ ( k , m ) + {A}^{-} ( k , m ) {∠φ}^{-} ( k , m ) ] , \\ wherein \\ A ( k , m ) = \frac{{A}_{x} ( k )}{2} [ \frac{sin π ( {f}_{x} ( k ) - m )}{sin [ π ( {f}_{x} ( k ) - m ) / N ]} ] , \\ φ ( k , m ) = {φ}_{x} ( k ) + π ( {f}_{x} ( k ) - m ) ( N - 1 ) / N , \\ {A}^{-} ( k , m ) = \frac{{A}_{x} ( k )}{2} [ \frac{sin π ( {f}_{x} ( k ) + m )}{sin [ π ( {f}_{x} ( k ) + m ) / N ]} ] , \\ and \\ {φ}^{-} ( k , m ) = - {φ}_{x} ( k ) - π ( {f}_{x} ( k ) + m ) ( N - 1 ) / N \qquad ( 9 )$$

Next, step (S130) is to determine the frequency parameter fₓ(k) and the amplitude parameter Aₓ(k). Generally, a function representing a periodic signal includes frequency parameters, amplitude parameters and phase parameters. In order to maintain the characteristics of the time domain signal in the initial frequency spectrum, it is needed to determine the frequency parameter and the amplitude parameter first. Since the sub-component with the largest amplitude has relatively less noise and is disturbed less, the frequency parameter and the amplitude parameter are thus based upon the sub-components with the largest and the second largest amplitudes.

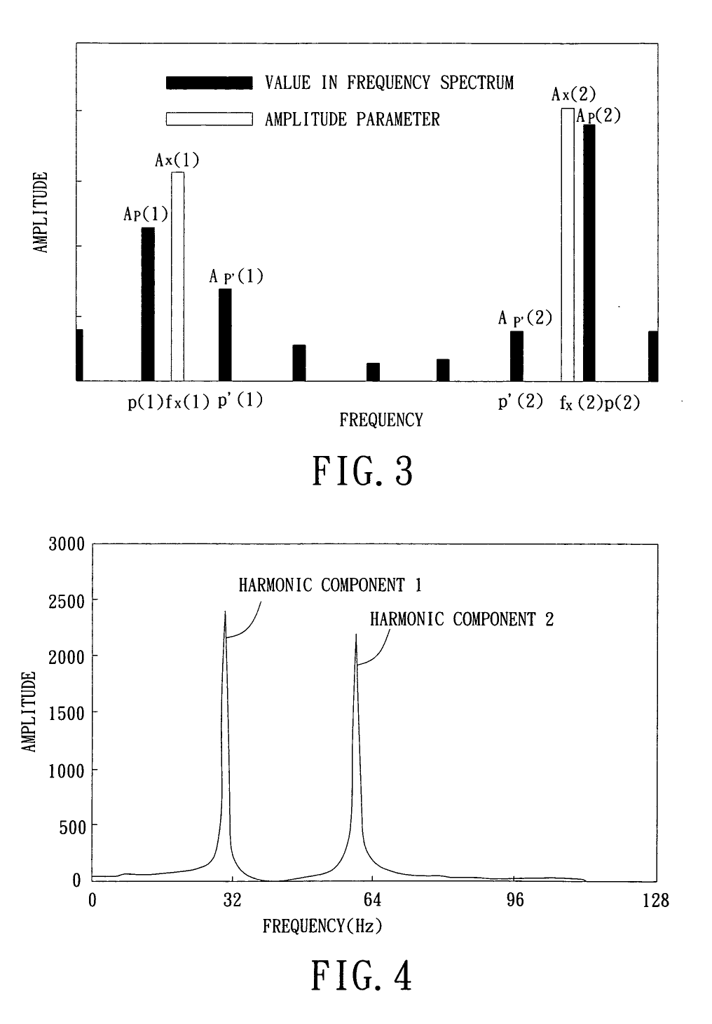

Referring to FIG. 2, step (S130) includes two sub-steps. In sub-step (S131), for each of the harmonic components of the frequency domain signal, amplitudes of a largest sub-component and a second largest sub-component thereof are expressed as functions of the frequency parameter and the amplitude parameter. Subsequently, sub-step (S132) is to determine the frequency parameter and the amplitude parameter based upon the functions obtained in sub-step (S131). As shown in FIG. 3, the initial sampling signal has two harmonic components 1, 2 in the initial frequency spectrum. The amplitudes of the largest sub-components of the two harmonic components 1, 2 are Aₚ(1) and Aₚ(2) respectively, and correspond to the graduations p(1) and p(2) of the initial frequency spectrum, respectively. The amplitudes of the second largest sub-components of the two harmonic components 1, 2 are A_{p′}(1) and A_{p′}(2) respectively, and correspond to the graduations p′(1) and p′(2) of the initial frequency spectrum, respectively.

When the initial sampling signal has K harmonic components, the amplitude of the largest sub-component of the k^{th} harmonic component can be represented by

$${A}_{p} ( k ) = \frac{{A}_{x} ( k )}{2} \frac{sin [ π ( {f}_{x} ( k ) - p ( k ) ) ]}{sin [ π ( {f}_{x} ( k ) - p ( k ) ) / N ]} , \qquad ( 10 )$$

wherein p(k) is a graduation corresponding to the largest sub-component of the k^{th} harmonic component. The amplitude of the second largest sub-component of the k^{th} harmonic component can be represented by

$${A}_{{p}^{′}} ( k ) = \frac{{A}_{x} ( k )}{2} \frac{sin [ π ( {f}_{x} ( k ) - {p}^{′} ( k ) ) ]}{sin [ π ( {f}_{x} ( k ) - {p}^{′} ( k ) ) / N ]} , \qquad ( 11 )$$

wherein p′(k) is a graduation corresponding to the second largest sub-component of the k^{th} harmonic component.

According to Equations 10 and 11, the following equation can be obtained.

$$\begin{matrix}\frac{{A}_{p} ( k )}{{A}_{{p}^{′}} ( k )} = \frac{sin [ π ( {f}_{x} ( k ) - p ( k ) ) ] \cdot sin [ π ( {f}_{x} ( k ) - {p}^{′} ( k ) ) / N ]}{sin [ π ( {f}_{x} ( k ) - {p}^{′} ( k ) ) ] \cdot sin [ π ( {f}_{x} ( k ) - p ( k ) ) / N ]} \\ = - [ \begin{matrix}cos ( \frac{π ( {p}^{′} ( k ) - p ( k ) )}{N} ) - sin ( \frac{π ( {p}^{′} ( k ) - p ( k ) )}{N} ) \cdot \\ cot ( \frac{π ( {f}_{x} ( k ) - p ( k ) )}{N} )\end{matrix} ]\end{matrix} \qquad ( 12 )$$

According to Equation 12, the frequency parameter of the k^{th} harmonic component can be expressed as

$${f}_{x} ( k ) = p ( k ) + ( {p}^{′} ( k ) - p ( k ) ) \frac{{A}_{p} ( k )}{{A}_{p} ( k ) + {A}_{{p}^{′}} ( k )} . \qquad ( 13 )$$

Additionally, a graduation difference between the frequency parameter fₓ(k) and the graduation p(k) of the k^{th} harmonic component is

f_{d}(k)=fₓ(k)−p(k). (14)

According to Equations 10 and 14, the amplitude parameter Aₓ(k) of the k^{th} harmonic component can be expressed as

$${A}_{x} ( k ) = \frac{2 π {f}_{d} ( k )}{N sin ( π {f}_{d} ( k ) )} {A}_{p} ( k ) . \qquad ( 15 )$$

Moreover, since the phase parameter φₓ(k) does not affect leakage energy, the frequency parameter fₓ(k) and the amplitude parameter Aₓ(k) based upon the initial frequency spectrum are sufficient for obtaining an optimized frequency spectrum.

Next, step (S140) is to establish a leakage energy equation and determine a graduation shifting quantity based upon the frequency parameter fₓ(k) and the amplitude parameter Aₓ(k) obtained in step (S130), the number N of the sample points in the first subset in step (S110), and the graduations of the initial frequency spectrum that are associated with the harmonic components of the frequency domain signal in step (S120). Subsequently, step (S150) is to determine an optimum number of sample points that will result in minimum leakage energy.

After obtaining the frequency parameter fₓ(k) and the amplitude parameter Aₓ(k) for each of the harmonic components, optimum graduations of an optimized frequency spectrum can be determined according to the frequency parameter fₓ(k) and the amplitude parameter Aₓ(k). Therefore, the graduations of the optimized frequency spectrum are associated with harmonic components of a frequency domain signal transformed from an adjusted sampling signal, such that the leakage energy is reduced. A method for determining the graduations of the optimized frequency spectrum is to shift the graduations of the initial frequency spectrum to enable the harmonic components of the frequency domain signal to be associated with the shifted graduations. Therefore, energy of the harmonic components is more concentrated, and the leakage energy is reduced. This method for determining the graduations according to minimum leakage energy is the way to optimize the frequency spectrum.

An equation showing a relationship among the leakage energy, the frequency parameter fₓ(k), the amplitude parameter Aₓ(k) and the graduation difference f_{d}(k) is the leakage energy equation. When the initial sampling signal has K harmonic components, total energy of the initial sampling signal can be represented by

$${S}^{2} = {\sum }_{k = 1}^{K} {A}_{x}^{2} ( k ) . \qquad ( 16 )$$

Moreover, the total energy is a total amount of energy in a real frequency domain and energy in an imaginary frequency domain. Therefore, the total energy of the initial sampling signal can be also expressed as

$${S}^{2} = 2 \cdot {\sum }_{k = 1}^{K} {( {A}_{p} ( k ) / N )}^{2} + 2 L , \qquad ( 17 )$$

wherein L is the leakage energy. According to Equations 16 and 17,

$${\sum }_{k = 1}^{K} {A}_{x}^{2} ( k ) = 2 \cdot {\sum }_{k = 1}^{K} {( {A}_{p} ( k ) / N )}^{2} + 2 L . \qquad ( 18 )$$

Equation 15 can be expressed as a Taylor series expansion, that is,

$${A}_{p} ( k ) = {NA}_{x} ( k ) [ \begin{matrix}{lim}_{{f}_{d} ( k ) \to 0} \frac{sin ( π {f}_{d} ( k ) )}{2 π {f}_{d} ( k )} + \\ {lim}_{{f}_{d} ( k ) \to 0} \frac{\begin{matrix}( cos ( π {f}_{d} ( k ) ) ) ( 2 {π}^{2} {f}_{d} ( k ) ) - \\ 2 π sin ( π {f}_{d} ( k ) )\end{matrix}}{{( 2 π {f}_{d} ( k ) )}^{2}} {f}_{d} ( k ) + …\end{matrix} ] . \qquad ( 19 )$$

Whereas, according to L'Hospital's rule,

$$\begin{matrix}{lim}_{{f}_{d} ( k ) \to 0} \frac{sin ( π {f}_{d} ( k ) )}{2 π {f}_{d} ( k )} = \frac{π cos ( π {f}_{d} ( k ) )}{2 π} = \frac{1}{2} cos ( π {f}_{d} ( k ) ) , \\ and & ( 20 ) \\ {lim}_{{f}_{d} ( k ) \to 0} \frac{\begin{matrix}( cos ( π {f}_{d} ( k ) ) ) ( 2 {π}^{2} {f}_{d} ( k ) ) - \\ 2 π sin ( π {f}_{d} ( k ) )\end{matrix}}{{( 2 π {f}_{d} ( k ) )}^{2}} = \frac{- π sin ( π {f}_{d} ( k ) )}{4} . & ( 21 )\end{matrix}$$

Equation 19 can be rearranged as

$${A}_{p} ( k ) = {NA}_{x} ( k ) ( \frac{1}{2} cos ( π {f}_{d} ( k ) ) - \frac{π sin ( π {f}_{d} ( k ) )}{4} \cdot {f}_{d} ( k ) + … ) , \qquad ( 22 )$$

and can be approximated as

$${A}_{p} ( k ) ≅ \frac{{NA}_{x} ( k )}{2} cos ( π {f}_{d} ( k ) ) . \qquad ( 23 )$$

Thus, the leakage energy equation can be expressed as

$$L ≅ {N}^{2} {\sum }_{k = 1}^{K} {[ \frac{{A}_{x} ( k )}{2} sin ( π {f}_{d} ( k ) ) ]}^{2} \qquad ( 24 )$$

Herein, the frequency parameter fₓ(k) and the amplitude parameter Aₓ(k) are known numbers. It is needed to shift the graduations of the initial frequency spectrum for reducing the leakage energy L. The graduations of the optimized frequency spectrum can be determined according to the optimum number N′ of sample points and the graduation shifting quantity Sₛ. The optimum number N′ of sample points determines an interval between graduations, and the graduation shifting quantity Sₛ is to make all the graduations increase or decrease by a certain quantity. When the optimum number N′ of sample points and the graduation shifting quantity Sₛ are adjustable, the relationship between the m^{th} graduation g′(m) of the optimized frequency spectrum and the m^{th} graduation g(m) of the initial frequency spectrum can be represented by

g′(m)=(g(m)+Sₛ)N/N′ (25)

Since the graduations have been shifted, intervals between the harmonic components and the graduations change. The number of sample points is adjusted before a shift in the graduations. The graduation difference also changes, because the number of sample points is adjusted. Herein, the graduation difference is obtained when the number of sample points is adjusted, and the graduations are not shifted yet. Thus, the adjusted graduation difference f_{d}′(k) can be represented by

f_{d}(k)=f(k)−m·N/N′, (26)

wherein

|fₓ(k)−m·N/N′|=min{|fₓ(k)−m·N/N′|, m=0,1, . . . , N}. (27)

Equation 26 shows an interval between the frequency parameter fₓ(k) of the harmonic components and an adjacent graduation. Moreover, an adjusted leakage energy equation L′ represents the leakage energy after graduation shifting, that is,

$${L}^{′} ≅ {\sum }_{k = 1}^{K} {[ \frac{{A}_{x} ( k )}{2} sin ( π {N}^{′} \frac{{f}_{d}^{′} ( k ) - {S}_{s}}{N} ) ]}^{2} . \qquad ( 28 )$$

At a certain number of sample points, the graduation shifting quantity that will result in minimum leakage energy is

$${S}_{s} = \frac{{\sum }_{k = 1}^{K} {A}_{x}^{2} ( k ) {f}_{d}^{′} ( k )}{{\sum }_{k = 1}^{K} {A}_{x}^{2} ( k )} . \qquad ( 29 )$$

Due to graduation shifting, the leakage energy is reduced to a minimum value at the certain number of sample points, and thus Equation 28 can be expressed as a minimum leakage energy equation, that is,

$${L}_{min} = {\sum }_{{k}^{′} = 1}^{K} {\sum }_{k = 1}^{K} {A}_{x} ( {k}^{′} ) {A}_{x} ( k ) \vert {f}_{d}^{′} ( {k}^{′} ) - {f}_{d}^{′} ( k ) \vert . \qquad ( 30 )$$

Different numbers of sample points correspond to different values of the minimum leakage energy equation Lₘᵢₙ after graduation shifting. An extreme value of the minimum leakage energy equation Lₘᵢₙ is attributed to a particular number of sample points, that is, the optimum number of sample points.

Step (S160) is to obtain the adjusted sampling signal based upon a second subset of sample points, wherein the number of the sample points in the second subset is equal to the optimum number obtained in step (S150). Finally, an optimized frequency domain signal is obtained by transforming the adjusted sampling signal in step (S170). The optimized frequency domain signal has harmonic components associated with the graduations of the optimized frequency spectrum, wherein the graduations of the optimized frequency spectrum are calculated based upon the graduations of the initial frequency spectrum, the graduation shifting quantity SS obtained in step (S140), the number N of sampling points in the first subset, and the optimum number N′ obtained instep (S150). The optimized frequency domain signal can be expressed as

$$X ( m ) = {\sum }_{n = 0}^{{N}^{′} - 1} x ( n ) exp ( \frac{- j 2 π n}{{N}^{′}} ( m - {S}_{s} ) ) , \qquad ( 31 )$$

wherein m ranges from 0 to N′−1.

After shifting the graduations, the actual graduations of the optimized frequency spectrum are

f_{scale}(m)=(m+Sₛ)N/(TN′), (32)

wherein m ranges from 0 to N′−1.

It is noted that, a product of the adjusted sampling signal and a cosine function of the graduation shifting quantity is a real part Xᵣ(m) of the adjusted sampling signal in the real time domain. Additionally, a product of the adjusted sampling signal and a sine function of the graduation shifting quantity is an imaginary part Xᵢ(m) of the adjusted sampling signal in the imaginary time domain. DFT is used to transform the adjusted sampling signal to the optimized frequency domain signal to obtain the optimized frequency spectrum. Equation 31 can be expressed by

X(m)=Xᵣ(m)+jXᵢ(m), (33)

wherein m ranges from 0 to N′−1,

$${X}_{r} ( m ) = {\sum }_{n = 0}^{{N}^{′} - 1} x ( n ) cos ( 2 π n \frac{{S}_{s}}{{N}^{′}} ) exp ( - j 2 π n \frac{m}{{N}^{′}} ) , \\ and$$

$${X}_{i} ( m ) = {\sum }_{n = 0}^{{N}^{′} - 1} x ( n ) sin ( 2 π n \frac{{S}_{s}}{{N}^{′}} ) exp ( - j 2 π n \frac{m}{{N}^{′}} ) .$$

The aforementioned method for shifting the graduations maintains the characteristics of the time domain signal, and reduces unnecessary components in the optimized frequency spectrum when shifting the graduations. The real part Xᵣ(m) and the imaginary part Xᵢ(m) cause the optimized sampling signal to experience a carrier effect, and unnecessary vectors of the real part Xᵣ(m) and the imaginary part Xᵢ(m) cancel out each other, such that the optimized frequency spectrum represents the characteristics of the time domain signal.

Referring to FIGS. 4 to 9, there is an example of the embodiment according to the present invention. The initial sampling signal includes two harmonic components 1 and 2, that is,

x(t)=10 cos(2π·30.2t)+10 cos(2π·60.3t) (34)

The predetermined sampling frequency is 512 (s/sec), and the number of sample points is 534. The initial sampling signal is obtained based upon a first subset of the sample points, wherein the number of the sample points in the first subset is 512. FFT is used to transform the initial sampling signal to obtain the initial frequency spectrum in FIG. 4.

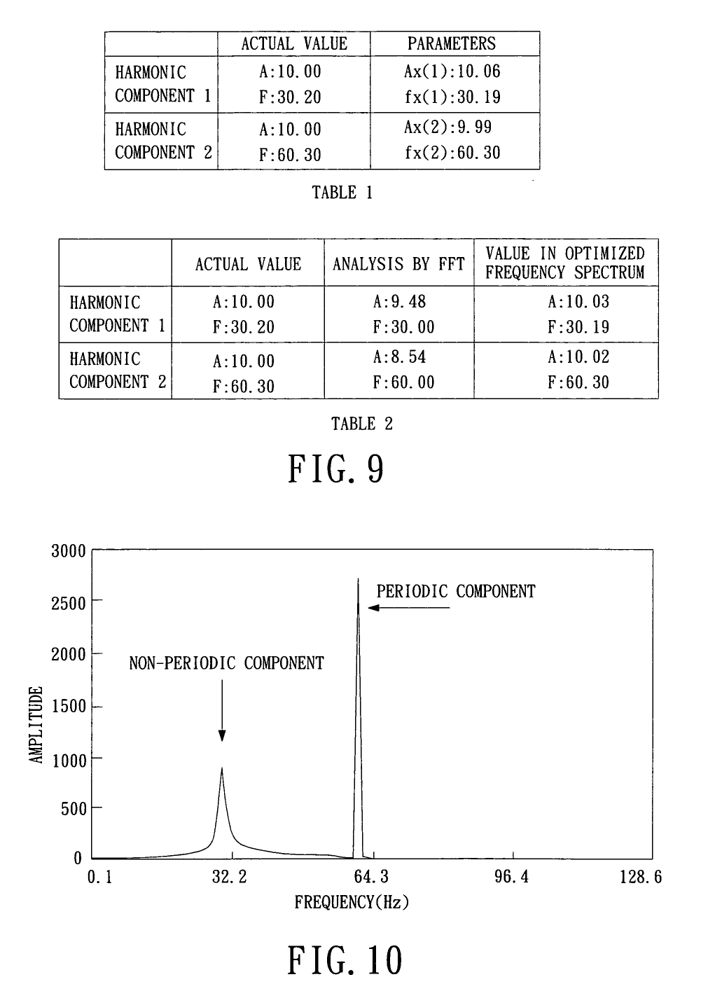

According to Equations 13 and 15, the frequency parameters fₓ(1), fₓ(2) and the amplitude parameters Aₓ(1), Aₓ(2) of the harmonic components 1, 2 are obtained, respectively. Referring to FIG. 9, Table 1 is a result of the frequency parameters fₓ(1), fₓ(2) and the amplitude parameters Aₓ(1), Aₓ(2) of the harmonic components 1, 2.

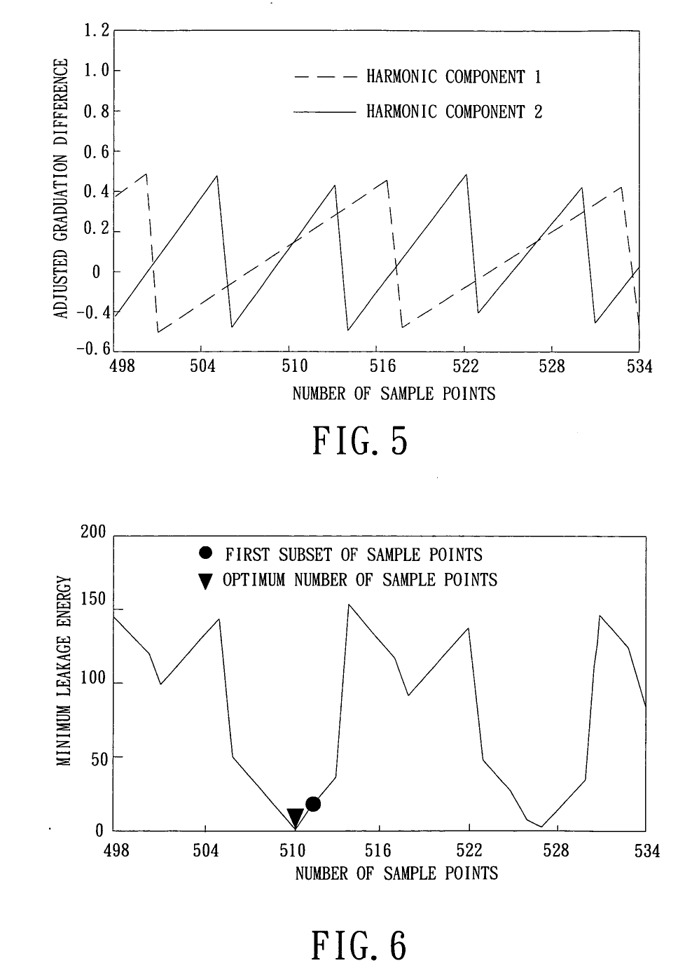

The next step is to establish the leakage energy equation L and determine the graduation shifting quantity Sₛ. Then, the adjusted graduation difference f_{d}′(k) is calculated based upon Equation 26 to obtain FIG. 5. Subsequently, the minimum leakage energy equation Lₘᵢₙ is established according to the leakage energy equation L, the graduation shifting quantity Sₛ, and the adjusted graduation difference f_{d}′(k). According to Equation 30, the minimum leakage energy for each of numbers (498-534) of sample points is calculated as shown in FIG. 6.

From FIG. 6, the extreme minimum value of the minimum leakage energy equation Lₘᵢₙ is at the number 510 of sample points, i.e., 510 is the optimum number of sample points. Next, the graduation shifting quantity Sₛ is obtained according to Equation 29 and the optimum number of sample points. In this example, the graduation shifting quantity Sₛ is equal to 0.07, and then the graduations of the optimized frequency spectrum can be obtained.

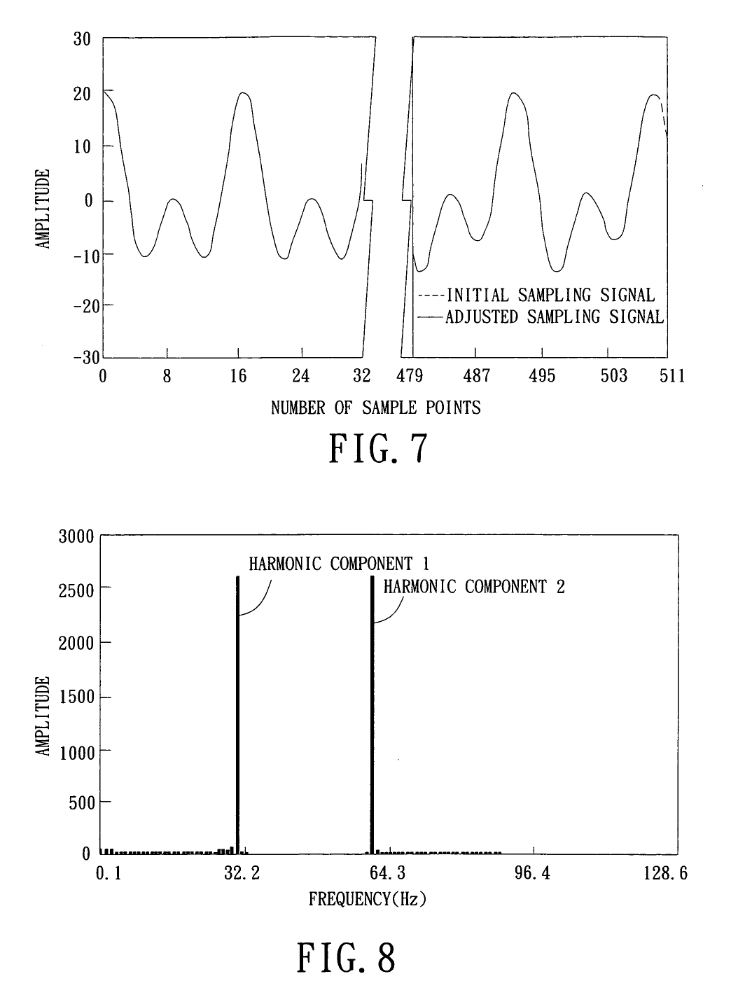

As shown in FIG. 7, the adjusted sampling signal includes the complete characteristics of the initial sampling signal. The adjusted sampling signal can be expressed as Equation 33, and DFT is then used to transform the adjusted sampling signal to the optimized frequency domain signal to obtain the optimized frequency spectrum as shown in FIG. 8.

From FIGS. 4 and 8, although the graduations of the initial frequency spectrum in FIG. 4 and the graduations of the optimized frequency spectrum in FIG. 8 are similar, the energy of each of the harmonic components 1 and 2 is concentrated in a corresponding graduation respectively. Therefore, the picket-fence effect and the leakage effect are desirably reduced, and values read from the optimized frequency spectrum are accurate.

Referring to FIG. 9, Table 2 shows a result of the values of the frequencies and amplitudes of the harmonic components 1 and 2 in FIG. 8. The values of the frequencies and amplitudes obtained according to the present invention are relatively closer to actual values than values analyzed solely by FFT. Therefore, accuracy of the frequency spectrum is enhanced according to the present invention.

Additionally, the method of the present invention can be used to analyze a non-periodic signal, for example,

x(t)=10e^{-2.5t}cos(2π·30.2t)+10 cos(2π·60.3t). (35)

An analysis result is shown in FIG. 10. Because the harmonic component 1 is not periodic, it has a non-zero frequency bandwidth in the frequency spectrum. Essentially, a frequency bandwidth of a non-periodic component is not zero, and therefore the periodic and non-periodic components are clearly distinguishable after the analysis via the method according to the present invention.

In sum, on a premise of maintaining the characteristics of the time domain signal, the graduations of the optimized frequency spectrum that will result in the minimum leakage energy are selected from the nearby graduations of the initial frequency spectrum. Then, the adjusted sampling signal is transformed to the optimized frequency domain signal according to the optimum number of sample points and the graduations of the optimized frequency spectrum. Therefore, the leakage effect and the picket-fence effect are reduced, and the optimized frequency spectrum is relatively accurate.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

What is claimed is:

1. A method for optimization of a frequency spectrum, comprising the following steps:
a) sampling a time domain signal at a number of sample points, and obtaining an initial sampling signal based on a first subset of the sample points;
b) transforming the initial sampling signal to a frequency domain signal having harmonic components associated with graduations of an initial frequency spectrum;
c) determining a frequency parameter and an amplitude parameter for each of the harmonic components of the frequency domain signal obtained in step b);
d) establishing a leakage energy equation and determining a graduation shifting quantity based upon the frequency parameters and the amplitude parameters obtained in step c), the number of sample points in the first subset, and the graduations of the initial frequency spectrum that are associated with the harmonic components of the frequency domain signal in step b);
e) determining an optimum number of sample points that will result in a minimum value of the leakage energy equation;
f) obtaining an adjusted sampling signal based on a second subset of the sample points, wherein the number of the sample points in the second subset is equal to the optimum number obtained in step e); and
g) transforming the adjusted sampling signal to an optimized frequency domain signal having harmonic components associated with graduations of an optimized frequency spectrum, wherein the graduations of the optimized frequency spectrum are calculated based upon the graduations of the initial frequency spectrum, the graduation shifting quantity determined in step d), the number of sample points in the first subset, and the optimum number obtained in step e).

2. The method for optimization of a frequency spectrum as claimed in claim 1, wherein at least three identical waveforms are contained in the time domain signal during duration of sampling in step a) when the time domain signal is a periodic signal.

3. The method for optimization of a frequency spectrum as claimed in claim 1, wherein Fast Fourier Transform is used to transform the initial sampling signal in step b).

4. The method for optimization of a frequency spectrum as claimed in claim 1, wherein Discrete Fourier Transform is used to transform the initial sampling signal in step b).

5. The method for optimization of a frequency spectrum as claimed in claim 1, wherein Discrete Fourier Transform is used to transform the adjusted sampling signal in step g).

6. The method for optimization of a frequency spectrum as claimed in claim 1, wherein step c) includes the following sub-steps:
c1) for each of the harmonic components of the frequency domain signal, expressing amplitudes of a largest sub-component and a second largest sub-component thereof as functions of the frequency parameter and the amplitude parameter; and
c2) determining the frequency parameter and the amplitude parameter based on the functions obtained in sub-step c1).
